(19) United States
(12) Patent Application Publication
(10) Pub. No.: US 2025/0185395 A1
(43) Pub. Date: Jun. 5, 2025

(54) IMAGE SENSOR AND ELECTRONIC DEVICE

(71) Applicant: Samsung Electronics Co., Ltd., Suwon-si (KR)

(72) Inventors: Feifei FANG, Suwon-si (KR); Sungyoung YUN, Suwon-si (KR); Juhyung LIM, Suwon-si (KR); Hyeong-Ju KIM, Suwon-si (KR); Kyung Bae PARK, Suwon-si (KR); Jeong Il PARK, Suwon-si (KR); Hiromasa SHIBUYA, Suwon-si (KR); Jeoung In YI, Suwon-si (KR); Younhee LIM, Suwon-si (KR); Tae Jin CHOI, Suwon-si (KR); Hyerim HONG, Suwon-si (KR)

(73) Assignee: Samsung Electronics Co., Ltd., Suwon-si (KR)

(21) Appl. No.: 18/936,321

(22) Filed: Nov. 4, 2024

(30) Foreign Application Priority Data
Dec. 4, 2023 (KR) 10-2023-0173597

(51) Int. Cl. H01L 27/146; H10K 19/20; H10K 39/32

(52) U.S. Cl. CPC H10F 39/8053; H10F 39/182; H10K 19/20; H10K 39/32

(57) ABSTRACT

An image sensor includes a semiconductor substrate including a plurality of photodiodes, a color filter layer on the semiconductor substrate and including a plurality of color filters arranged along an in-plane direction of the semiconductor substrate, and an organic intermediate layer between the semiconductor substrate and the color filter layer and including a singlet fission material. An extinction coefficient of the organic intermediate layer at a maximum absorption wavelength is greater than or equal to 1×10⁴ cm⁻¹, and a singlet fission efficiency of the organic intermediate layer is greater than 50%.

### CROSS-REFERENCE TO RELATED APPLICATION

This application claims priority to and the benefit of Korean Patent Application No. 10-2023-0173597 filed in the Korean Intellectual Property Office on Dec. 4, 2023, the entire contents of which are incorporated herein by reference.

### BACKGROUND

Various example embodiments relate, in general, to image sensors and/or electronic devices.

An imaging device such as a camera or a device included in a camera includes an imaging device that captures an image and stores the captured image as an electrical signal. The imaging device includes an image sensor that decomposes incident light according to a wavelength to convert each component into an electrical signal.

Recently, in order to increase the resolution of image sensors, it is required to integrate many pixels per unit area. Accordingly, the size of each pixel becomes smaller, and as a result, the absorption area of silicon within each pixel is not sufficient, which limits the ability to achieve high sensitivity.

### SUMMARY

Some example embodiments may provide an image sensor with high integration and/or high sensitivity characteristics.

Alternatively or additionally, some example embodiments provide an electronic device including the image sensor.

According to some example embodiments, an image sensor includes a semiconductor substrate including a plurality of photodiodes, a color filter layer on the semiconductor substrate and including a plurality of color filters arranged along an in-plane direction of the semiconductor substrate, and an organic intermediate layer between the semiconductor substrate and the color filter layer and including a singlet fission material An extinction coefficient of the organic intermediate layer at a maximum absorption wavelength is greater than or equal to 1×10⁴ cm⁻¹, and a singlet fission efficiency of the organic intermediate layer is greater than 50%.

Alternatively or additionally according to some example embodiments, in an image sensor configured to obtain an image by combining image signals obtained by photoelectrically converting light in a red wavelength spectrum, a green wavelength spectrum, and a blue wavelength spectrum, an image sensor includes a color filter layer including a first color filter configured to selectively transmit light including a red wavelength spectrum, a second color filter configured to selectively transmit light including a green wavelength spectrum, and a third color filter configure to selectively transmit light including a blue wavelength spectrum, an organic intermediate layer including an organic material configured to absorb light transmitted through the color filter layer, to convert the absorbed light into photoelectricity, and that satisfies an energy level of the Relation Formula 1, an inorganic photodiode on the organic intermediate layer, and an inorganic intermediate layer between the organic intermediate layer and the inorganic photodiode and including at least one of an oxide, nitride, oxynitride, fluoride or oxyfluoride including a metal or a semi-metal. A maximum external quantum efficiency of the image sensor in at least one of a red wavelength spectrum, a green wavelength spectrum, or a blue wavelength spectrum is greater than a maximum external quantum efficiency of the inorganic photodiode in the same wavelength spectrum.

According to some example embodiments, an electronic device including the image sensor is provided.

By increasing the photoelectric conversion efficiency of the image sensor, highly integration and/or high sensitivity characteristics may be realized.

### BRIEF DESCRIPTION OF THE DRAWINGS

FIG. 1 is a cross-sectional view showing an example of an image sensor according to some example embodiments,

FIG. 2 is a schematic view illustrating an example of a camera, which is an example of an electronic device according to some example embodiments,

FIG. 3 is a graph showing the external quantum efficiency according to the wavelength of the image sensors according to Examples 1 and 2 and Reference Example 1,

FIG. 4 is a graph showing the external quantum efficiency according to the wavelength of the image sensors according to Examples 3 and 4 and Reference Example 1,

FIG. 5 is a graph showing the external quantum efficiency according to the wavelength of the image sensors according to Examples 5 and 6 and Reference Example 1, and

FIG. 6 is a graph showing the external quantum efficiency according to the wavelength of the image sensors according to Example 7 and Reference Examples 1 and 2.

### DETAILED DESCRIPTION OF EXAMPLE EMBODIMENTS

Hereinafter, various example embodiments of will be described in detail so that a person of ordinary skill in the art would understand the same. However, this disclosure may be embodied in many different forms and is not to be construed as limited to the exemplary embodiments set forth herein.

In the drawings, the thickness of layers, films, panels, regions, etc., are exaggerated for clarity. It will be understood that when an element such as a layer, film, region, or substrate is referred to as being “on” another element, it may be directly on the other element or intervening elements may also be present. In contrast, when an element is referred to as being “directly on” another element, there are no intervening elements present.

In the drawings, parts having no relationship with the description are omitted for clarity, and the same or similar constituent elements are indicated by the same reference numeral throughout the specification.

Hereinafter, the terms “lower portion” and “upper portion” are for convenience of description and do not limit the positional relationship.

As used herein, when a definition is not otherwise provided, “substituted” refers to replacement of a hydrogen atom of a compound by a substituent selected from among a halogen atom, a hydroxyl group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, phosphoric acid or a salt thereof, a silyl group, a C1 to C20 alkyl group, a C2 to C20 alkenyl group, a C2 to C20 alkynyl group, a C6 to C30 aryl group, a C7 to C30 arylalkyl group, a C1 to C30 alkoxy group, a C1 to C20 heteroalkyl group, a C3 to C20 heteroaryl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, and a combination thereof.

As used herein, when a definition is not otherwise provided, “hetero” refers to one including 1 to 4 heteroatoms selected from N, O, S, Se, Te, Si, and P.

Hereinafter, “combination” refers to a mixture of two or more and a stack structure of two or more.

Hereinafter, when a definition is not otherwise provided, the energy level is the highest occupied molecular orbital (HOMO) energy level or the lowest unoccupied molecular orbital (LUMO) energy level.

Hereinafter, when a definition is not otherwise provided, a work function or an energy level is expressed as an absolute value from a vacuum level. In addition, when the work function or the energy level is referred to be deep, high, or large, it may have a large absolute value based on “0 eV” of the vacuum level while when the work function or the energy level is referred to be shallow, low, or small, it may have a small absolute value based on “0 eV” of the vacuum level. Further, the differences between the work function and/or the energy level may be values obtained by subtracting a small value of the absolute value from a large value of the absolute value.

Hereinafter, when a definition is not otherwise provided, the HOMO energy level may be evaluated with an amount of photoelectrons emitted by energy when irradiating UV light to a thin film using AC-3 (Riken Keiki Co., Ltd.).

Hereinafter, when a definition is not otherwise provided, the LUMO energy level may be obtained by obtaining an energy bandgap using a UV-Vis spectrometer (Shimadzu Corporation), and then calculating the LUMO energy level from the energy bandgap and the already measured HOMO energy level.

Hereinafter, an image sensor according to some example embodiments will be described.

An image sensor may converge an image of an object, convert it into an electrical signal and store it, and an image of the object may be obtained by combining the electrical signals obtained by photoelectrically converting light in the red wavelength spectrum, green wavelength spectrum, and blue wavelength spectrum. The image sensor may be, for example, a complementary metal-oxide semiconductor (CMOS) image sensor.

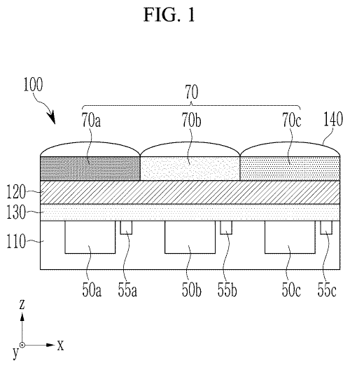

FIG. 1 is a cross-sectional view showing an example of an image sensor according to some example embodiments.

Referring to FIG. 1, the image sensor 100 according to some example embodiments includes a semiconductor substrate 110, a color filter layer 70, an organic intermediate layer 120, an inorganic intermediate layer 130, and a focusing lens 140.

The semiconductor substrate 110 may be or may include (or be included in) a silicon substrate or a compound semiconductor substrate, and photodiodes 50a, 50b, and 50c and charge storage units 55a, 55b, and 55c may be integrated or at least partially integrated therein. The photodiode 50a may be configured to sense light of a first wavelength spectrum that has passed through a first color filter 70a, which will be described later, the photodiode 50b may be configured to sense light of a second wavelength spectrum that has passed a second color filter 70b, which will be described later, and the photodiode 50c may be configured to sense light in the wavelength spectrum that has passed through the third color filter 70c, which will be described later

The photodiodes 50a, 50b, and 50c and charge storage units 55a, 55b, and 55c may be integrated for each pixel.

The photodiodes 50a, 50b, and 50c may include inorganic semiconductors, such as Si, Ge, GaAs, InP, GaN, AlN, CdTe, ZnTe, CIGS, or any combination thereof, but are not limited thereto.

The color filter layer 70 includes a plurality of color filters configured to selectively transmit one or two of various wavelengths such as the red wavelength spectrum, the green wavelength spectrum, or the blue wavelength spectrum, and includes a first color filter 70a, a second color filter 70b, and a third color filter 70c configured to selectively transmit light of at least different wavelength spectra.

The first, second, and third color filters 70a, 70b, and 70c are arranged along an in-plane direction (for example, an XY direction) of the semiconductor substrate 110, and unit color filters including at least one first color filter 70a, at least one second color filter 70b, and at least one third color filter 70c may be repeatedly arranged along rows and/or columns, for example as a Bayer pattern.

The first, second, and third color filters 70a, 70b, and 70c may be configured to selectively transmit light of a portion of the visible light wavelength spectrum. For example, the first color filter 70a may be configured to transmit light of a portion of the visible light wavelength spectrum, the second color filter 70b may be configured to selectively transmit light including the green wavelength spectrum, and the third color filter 70c may be configured to selectively transmit light including the blue wavelength spectrum. For example, the first color filter 70a may be or include (or be included in) a red filter, a magenta filter, and/or a yellow filter, for example, the second color filter 70b may be or include (or be included in) a green filter, a cyan filter, and/or a yellow filter, and for example, a third color filter 70c may be or include (or be included in) a blue filter, a cyan filter, and/or a magenta filter, and the first, second, and third color filters 70a, 70b, and 70c may be different from each other. For example, the first color filter 70a, the second color filter 70b, and the third color filter 70c may be a red filter, a green filter, and a blue filter, respectively.

The organic intermediate layer 120 may be or include or be included in an organic photoelectric conversion layer between the semiconductor substrate 110 and the color filter layer 70 and configure to absorb light passing through the color filter layer 70 and convert the absorbed light into an electrical signal.

The organic intermediate layer 120 includes a singlet fission material. The singlet fission material may be an organic light absorbing material configured to exhibit a phenomenon that the exciton in the singlet state (hereinafter referred to as “singlet exciton”) generated by absorbing one photon is divided into two excitons in the triplet state (hereinafter referred to as “triplet exciton”).

The singlet fission material may satisfy Relation Formula 1 to spontaneously exhibit this singlet fission.

$$E ( {S}_{1} ) + 0.5 eV \geq 2 \times E ( {T}_{1} ) \qquad [ Relation Formula 1 ]$$

In Relation Formula 1, E(S₁) is or corresponds to an excitation energy in a lowest singlet excited state of the singlet fission material, and E(T₁) is or corresponds to the excitation energy in a lowest triplet excited state of the singlet fission material.

In Relation Formula 1, E(S₁) may be or correspond to the energy required to excite from the ground state (S₀) to the lowest singlet excited state (S₁), and E(T₁) may be or correspond to the energy required to excite from the ground state (S₀) to the lowest triplet excited state (T₁). For example, E(S₁) may be an excitation energy in a lowest singlet excited state of the singlet fission material, and E(T₁) may be an excitation energy in a lowest triplet excited state of the singlet fission material. E(S₁) and E(T₁) may be density functional theory (DFT) values, for example DFT calculation values, and in some cases may specifically be calculated values under the DGDZVP basis set and B3LYP functional conditions.

The singlet fission material that satisfies Relation Formula 1 may generate amplified (e.g. approximately doubled) excitons by splitting from the singlet state (S₁) excited by light absorption to the triplet state (T₁), and these amplified excitons are transferred to the photodiodes 50a, 50b, and 50c within the semiconductor substrate 110 so as to increase the efficiency of the image sensor. Accordingly, the image sensor 100 may theoretically implement external quantum efficiency (EQE) greater than about 100%.

The singlet fission material may be configured to absorb light in at least one spectrum selected from the red wavelength spectrum, the green wavelength spectrum, or the blue wavelength spectrum, for example, light in at least two of the red wavelength spectrum, green wavelength spectrum, or blue wavelength spectrum, and for example, light in the red wavelength spectrum, green wavelength spectrum, and blue wavelength spectrum. The maximum absorption wavelength (λmax) of the singlet fission material may, for example, fall between about 380 nm to about 700 nm.

The light absorption characteristics of the singlet fission material may be substantially the same as the light absorption characteristics of the organic intermediate layer 120. Alternatively or additionally, an extinction coefficient at the maximum absorption wavelength (λₘₐₓ) of the singlet fission material may be greater than or equal to about 1×10⁴ cm⁻¹, within the above range, greater than or equal to about 1.5×10⁴ cm⁻¹, greater than or equal to about 1.8×10⁴ cm⁻¹, greater than or equal to about 2.0×10⁴ cm⁻¹, greater than or equal to about 2.5×10⁴ cm⁻¹, greater than or equal to about 3.0×10⁴ cm⁻¹, or greater than or equal to about 5.0×10⁴ cm⁻¹, within the above range, about 1×10⁴ cm⁻¹ to about 1.0×10⁶ cm⁻¹, about 1.5×10⁴ cm⁻¹ to about 1.0×10⁶ cm⁻¹, about 1.8×10⁴ cm⁻¹ to about 1.0×10⁶ cm⁻¹, about 2.0×10⁴ cm⁻¹ to about 1.0×10⁶ cm⁻¹, about 2.5×10⁴ cm⁻¹ to about 1.0×10⁶ cm⁻¹, about 3.0×10⁴ cm⁻¹ to about 1.0×10⁶ cm⁻¹ or about 5.0×10⁴ cm⁻¹ to about 1.0×10⁶ cm⁻¹, but is not limited thereto. In some examples, the extinction coefficient of the singlet fission material may be measured, for example, by vacuum thermally depositing the singlet fission material on a transparent plate to obtain a film, obtaining an absorbance at the maximum absorption wavelength (λₘₐₓ) using a Shimadzu UV-3600 Plus UV-Vis-NIR spectrometer for this film, and dividing it by the thickness of the film.

The excitation energy E(T₁) in the triplet state of the singlet fission material, that is, the energy required to excite from the ground state (S₀) to the triplet state (T₁), corresponds to the energy of the photodiodes 50a, 50b, and 50c. It may be equal to or greater than the energy bandgap of the inorganic semiconductor. For example, the difference between the excitation energy E(T₁) in the triplet state and the energy bandgap of the inorganic semiconductor of the photodiodes 50a, 50b, and 50c may be greater than or equal to about 0 V, and within the above range, greater than or equal to about 0.05 eV, greater than or equal to about 0.1 eV, greater than or equal to about 0.15 eV, or greater than or equal to about 0.2 eV, and within the above range, about 0 to about 5.0 eV, about 0.05 eV to about 5.0 eV, about 0.1 eV to about 5.0 eV, about 0.15 eV to about 5.0 eV, or about 0.2 eV to about 5.0 eV. By having the difference in the above range, the exciton amplified from the singlet fission material in the organic intermediate layer 120 may be effectively diffused and transferred to the photodiodes 50a, 50b, and 50c.

The singlet fission efficiency of the singlet fission material may be, for example, greater than about 50%. Herein, the singlet fission efficiency may be the percentage capable of generating triplet excitons from among the singlet excitons generated in the organic intermediate layer 120, and may be expressed, for example, by Relation Formula 2.

$${ϕ}_{fiss} = \frac{{k}_{fiss}}{{k}_{fiss} + {k}_{mon}} \times 100 \qquad [ Relation Formula 2 ]$$

In Relation Formula 2, ϕ_{fiss} is or corresponds to a singlet fission efficiency, k_{fiss} is or corresponds to a fission rate of a singlet exciton, and kₘₒₙ is or corresponds to a fluorescence decay rate of a singlet fission material in a solution state.

The singlet fission efficiency of the singlet fission material may be greater than or equal to about 55%, greater than or equal to about 60%, greater than or equal to about 65%, greater than or equal to about 70%, greater than or equal to about 75%, greater than or equal to about 80%, greater than or equal to about 85%, greater than or equal to about 90% or greater than or equal to about 95% or more, and may be up to 100% within the above range.

The singlet fission material is not particularly limited, may be an organic material that satisfies the aforementioned characteristics, and may be or include, for example, one or more of a monomer, dimer, or polymer. The singlet fission material may include for example polyacene, polyene, rylene, rubrene, a quinoid compound, biradicaloid, a derivative thereof, or any combination thereof, but is not limited thereto.

The polyacene may be selected from, for example, anthracene, tetracene, pentacene, hexacene, heptacene, phenacene, and a derivative thereof. For example, the polyacene or the derivative thereof may be represented by Chemical Formula 1.

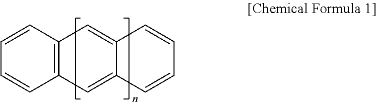

In Chemical Formula 1, n may be an integer from 1 to 20, and at least one hydrogen in at least one benzene ring may be replaced by deuterium, a halogen, a cyano group, a hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof. For example, at least one hydrogen of at least one benzene ring of Chemical Formula 1 may each independently exist or may be replaced by deuterium, a halogen, a cyano group, a hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof.

For example, the polyacene derivative may be an aromatic compound in which at least one hydrogen of polyacene is replaced by a dithienyl group, triisopropylsilyl (TIPS), phenyl group, butyl group, etc. Examples may include dithienyl tetracene, TIPS-tetracene, dibithienyl tetracene, diphenyl tetracene, TIPS-pentacene, diphenyl pentacene, dibiphenyl pentacene, dithienyl pentacene, dibithienyl pentacene, etc., but are limited thereto.

For example, the polyacene derivative may have a structure in which acenes such as anthracene, tetracene, pentacene, hexacene, heptacene, and phenacene are linked by a single bond, a C1 to C20 alkylene group, or a C6 to C30 arylene group. Such a polyacene derivative may be compounds listed in Group 1, but is not limited thereto.

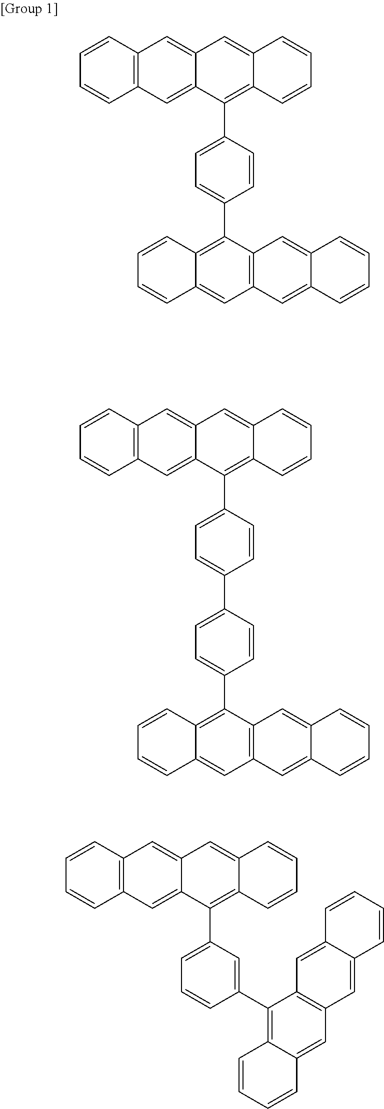

In the polyacenes listed in Group 1, at least one hydrogen in at least one benzene ring may be replaced by deuterium, a halogen, a cyano group, a hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof. For example, at least one hydrogen in at least one benzene ring of Chemical Formula 1-1 may each independently exist or may be replaced by deuterium, a halogen, a cyano group, a hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof.

The polyene may include C4 to C20 (e.g., C5 or more, C6 or more, or C7 or more and C18 or less or C15 or less) diene, C4 to C20 (e.g., C5 or more, C6 or more, or C7 or more and C18 or less or C15 or less) triene, C4 to C20 (e.g., C5 or more, C6 or more, or C7 or more and C18 or less or C15 or less) tetraene, C4 to C20 (e.g., C5 or more, C6 or more, or C7 or more and C18 or less or C15 or less) dienol, C4 to C20 (e.g., C5 or more, C6 or more, or C7 or more and C18 or less or C15 or less) trienol, C4 to C20 (e.g., C5 or more, C6 or more, or C7 or more and C18 or less or C15 or less) tetraenol, C4 to C20 (e.g., C5 or more, C6 or more, or C7 or more and C18 or less or C15 or less) dienone, C4 to C20 (e.g., C5 or more, C6 or more, or C7 or more and C18 or less or C15 or less) trienone, C4 to C20 (e.g., C5 or more, C6 or more, or C7 or more and C18 or less or C15 or less) traenone, a derivative thereof, or any combination thereof.

For example, the polyene may include butadiene, butadienol, butadienone, hexatriene, hexatrienol, hexatrienone, octatetraene, octatetraenol, octatetraenone, dodecadiene, dodecadienol, undecadienol, undecadienol, tridecadiene, tridedicaene, tridecadienol, tridecadienone, a derivative thereof, or any combination thereof. Herein, in the polyene derivative, at least one hydrogen present in the polyene chain may be replaced by deuterium, a halogen, a cyano group, hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof.

For example, the polyene derivative may include diphenylbutadiene, diphenylhexatriene, or diphenyloctatetraene, but is not limited thereto.

For example, the polyene may be one of the compounds listed in Group 2, but is not limited thereto.

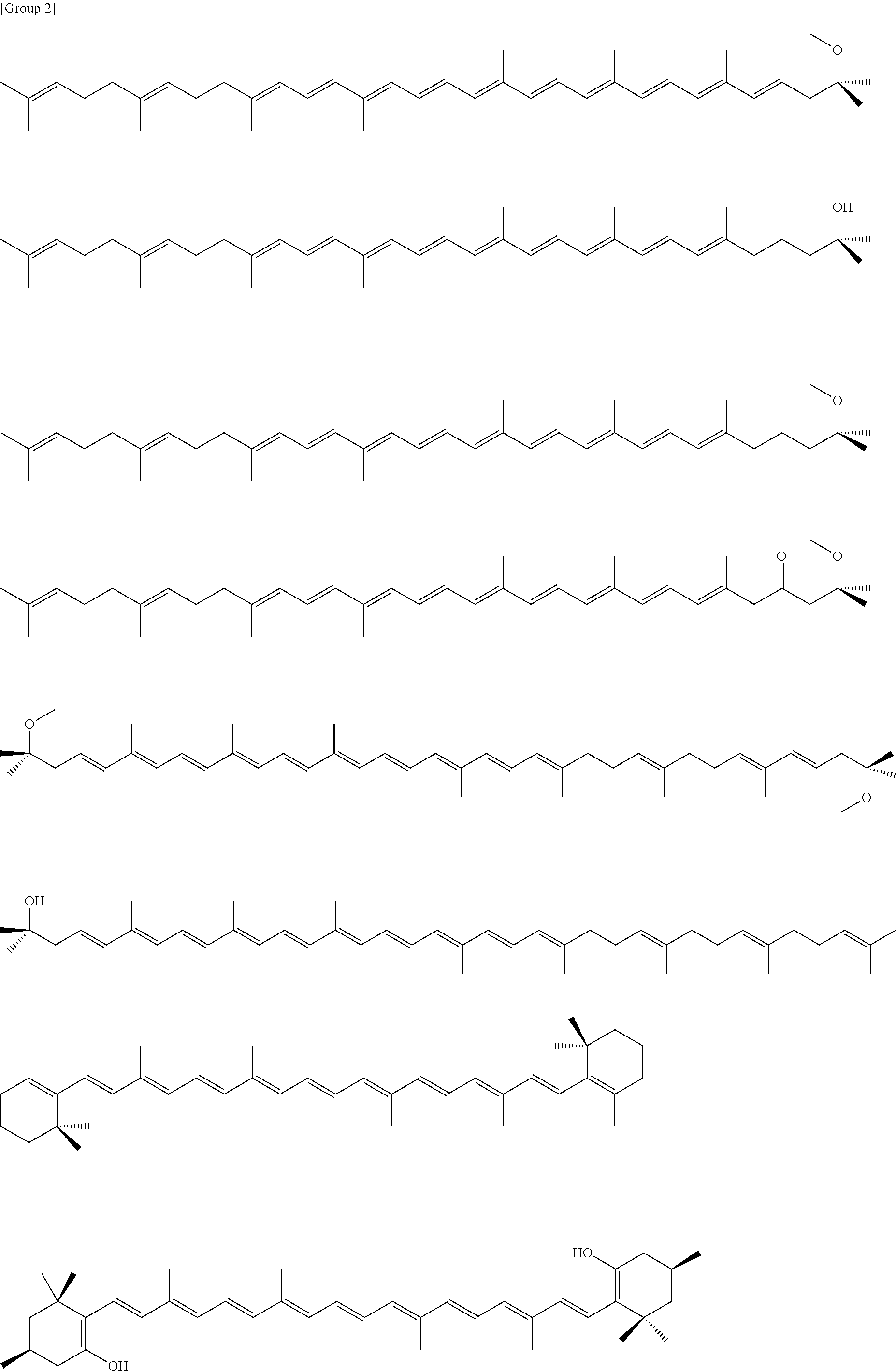

The rylene may include, for example, perylene, terylene, quatarylene, pentarylene, hexarylene, a derivative thereof, or any combination thereof.

For example, the rylene or the derivative thereof may be represented by Chemical Formula 3.

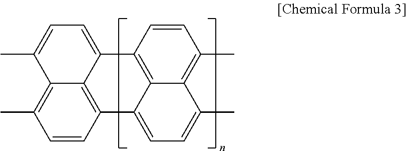

In Chemical Formula 3, n may be 1, 2, 3, 4, 5, 6, 7, or 8.

For example, at least one hydrogen in at least one benzene ring of Chemical Formula 3 may be replaced by deuterium, a halogen, a cyano group, a hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof. For example, at least one hydrogen in at least one benzene ring of Chemical Formula 3 may each independently exist or may be replaced by deuterium, a halogen, a cyano group, a hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof.

The rubrene or the derivative thereof may be represented by Chemical Formula 4.

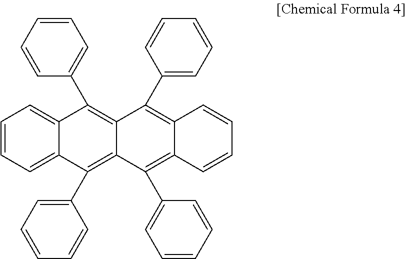 [SMILES: c1ccc(-c2c3ccccc3c(-c3ccccc3)c3c(-c4ccccc4)c4ccccc4c(-c4ccccc4)c23)cc1]

In Chemical Formula 4, at least one hydrogen in at least one benzene ring may be replaced by deuterium, a halogen, a cyano group, a hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof. For example, at least one hydrogen in at least one benzene ring of Chemical Formula 4 may each independently exist or may be replaced by deuterium, a halogen, a cyano group, a hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof.

The quinoid compound may be represented by Chemical Formula 5-1 or Chemical Formula 5-2.

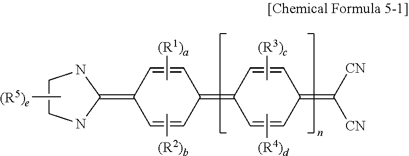

In Chemical Formula 5-1, R1, R2, R3, R4, and R5 may each independently be hydrogen, deuterium, a halogen, a cyano group, a hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof, a+b and c+d may each independently be 4 or less, e may be 0, 1, 2, 3 or 4, and n may be 0, 1 or 2.

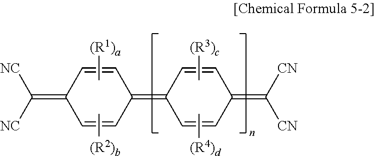

In Chemical Formula 5-2, R1, R2, R3, and R4 may each independently be hydrogen, deuterium, a halogen, a cyano group, a hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof, a, b, c, and d may each independently be an integer from 0 to 4, a+b and c+d may each independently be 4 or less, and n may be 0, 1 or 2.

The biradicaloid may include, for example, benzofuran, diphenyl isobenzofuran, a derivative thereof, or any combination thereof, but is not limited thereto.

The biradicaloid may include, but are not limited to, compounds listed in Group 3.

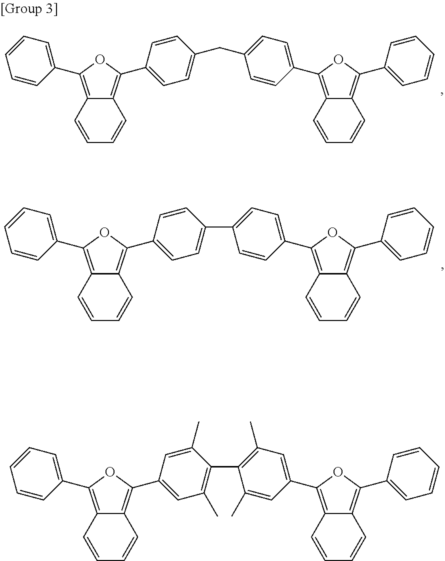 [SMILES: c1ccc(-c2oc(-c3ccc(Cc4ccc(-c5oc(-c6ccccc6)c6ccccc56)cc4)cc3)c3ccccc23)cc1 ; c1ccc(-c2oc(-c3ccc(-c4ccc(-c5oc(-c6ccccc6)c6ccccc56)cc4)cc3)c3ccccc23)cc1 ; Cc1cc(-c2oc(-c3ccccc3)c3ccccc23)cc(C)c1-c1c(C)cc(-c2oc(-c3ccccc3)c3ccccc23)cc1C]

In Group 3, at least one hydrogen in at least one benzene ring may be replaced by deuterium, a halogen, a cyano group, a hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof. For example, at least one hydrogen of at least one benzene ring of the compounds listed in Group 3 may each independently exist or may be replaced by deuterium, a halogen, a cyano group, a hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof.

The organic intermediate layer 120 may further include a phosphorescent dopant. The phosphorescent dopant may be configured to emit light by receiving energy from excitons that are amplified (e.g., approximately doubled) when a singlet fission material configured to absorb light and split from the excited singlet state (S₁) to the triplet state (T₁), and the inorganic semiconductors of the photodiodes 50a, 50b, and 50c may receive this luminous energy and be excited.

The energy bandgap of the phosphorescent dopant may be greater than or equal to the energy bandgap of the inorganic semiconductor of the photodiodes 50a, 50b, and 50c. For example, a difference between the energy bandgap of the phosphorescent dopant and the energy bandgap of the inorganic semiconductor of the photodiodes 50a, 50b, and 50c may be greater than or equal to about 0 V, within the above range, greater than or equal to about 0.05 eV, greater than or equal to about 0.1 eV, greater than or equal to about 0.15 eV, or greater than or equal to about 0.2 eV, and within the above range, about 0 to about 5.0 eV, about 0.05 eV to about 5.0 eV, 0.1 eV to about 5.0 eV, about 0.15 eV to about 5.0 eV, or about 0.2 eV to about 5.0 eV. By having an energy bandgap difference in the above range, excitons amplified from a singlet fission material within the organic intermediate layer 120 may be effectively diffused and transferred to the photodiodes 50a, 50b, and 50c.

The phosphorescent dopant may include, for example, metal porphyrin or a derivative thereof. The metal porphyrin may include, for example, Pt or Pd, such as Pt(II) meso tetraphenyl tetrabenzoporphyrin, Pt(II) tetraphenyl benzoporphyrin, Pt(II) octaethyl porphyrin, Pd(II) tetrabenzoporphyrin, Pt(II) meso tetra(pentafluorophenyl)porphyrin, Pt(II) tetrabenzoporphyrin, Pd(II) meso-tetraphenylporphyrin, Pt(II) aza-triphenyltetrabenzoporphyrin, Pt(II) tetraphenyl tetranaphthoporphyrin[2,3]porphyrin, or any combination thereof, but is not limited thereto.

The phosphorescent dopant may be included in an amount of about 0.1 to about 10 parts by weight based on 100 parts by weight of the singlet fission material.

The inorganic intermediate layer 130 may be between the semiconductor substrate 110 and the organic intermediate layer 120. For example, one surface of the inorganic intermediate layer 130 may be in contact with the semiconductor substrate 110, and the other surface of the inorganic intermediate layer 130 may be in contact with the organic intermediate layer 120.

The inorganic intermediate layer 130 may reduce or prevent quenching of excitons amplified in the organic intermediate layer 120, and/or may reduce or prevent electric charges (such as electrons and holes) generated from amplified excitons from being recombined on the surface of the semiconductor substrate 110, and accordingly, it may be possible to more easily extract electric charges moving from the organic intermediate layer 120 to the semiconductor substrate 110, thereby showing high charge extraction efficiency. Accordingly, the inorganic intermediate layer 130 may help the exciton amplified in the organic intermediate layer 120 to be ultimately implemented as improved photoelectric conversion efficiency of the image sensor 100, and as a result, high photoelectric conversion efficiency and thereby improved sensitivity and/or power consumption efficiency may be achieved.

The inorganic intermediate layer 130 may include, for example, an oxide, nitride, oxynitride, fluoride or oxyfluoride including a metal or a semi-metal, or any combination thereof. For example, the inorganic intermediate layer 130 may include an oxide, nitride, oxynitride, fluoride or oxyfluoride including Si, Al, Sr, Ba, Mg, Ge, Ga, Ti, Zr, Hf, Ta, Nb, La, Y, Bi, Pb, or any combination thereof, for example SiOₓ (0<x≤2), GeOₓ (0<x≤2), TiOₓ (0<x≤2), AlOₓ (0<x≤2), GaOₓ (0<x≤2), HfOₓ (0<x≤2), Al₂O₃, Ta₂O₅, La₂O₅, Y₂O₃, TiO₂, BaₓSr₁₋ₓTiO₃ (0<x<1, barium strontium titanate, BST), PbZrO₃, PbTiO₃, PbZrₓTi₁₋ₓO₃ (0<x<1), Pb₅Ge₃O₁₁, SrBi₂Ta₂O₉, BiLa₄TisO₁₂, Bi₄Ti₃O₁₂, SrBi₂(TaNb)₂O₉, BaZr_{0.2}Ti_{0.8}O₃ (barium zirconium titanate, BZT), BaTiO₃, SrTiO₃, Bi₄Ti₃O₁₂, SiNₓ (0<x≤2), GeNₓ (0<x≤2), TiNₓ (0<x≤2), AlNₓ (0<x≤2), GaNₓ (0<x≤2), HfNₓ (0<x≤2), SiOₓN₄₋ₓ (0<x<4, for example, 0.5≤x≤3), GeOₓN₄₋ₓ (0<x<4, for example, 0.5≤x≤3), TiOₓN_{y} (0.5≤x≤3 and 0<y≤2), AlOₓN_{y} (0.5≤x≤3, 0<y≤2), GaOₓN_{y} (0.5≤x≤3, 0<y≤2), HfOₓN_{y} (0.5≤x≤3, 0<y≤2), BaMgF₄, SrMgF₄, Ba₁₋ₓSrₓMgF₄ (0<x<1), BaZnF₄, Ba_{1-y}(Mg₁₋ₓZnₓ)_{1+y}F₄ (0≤x≤1, −0.2≤y≤0.2), BaMgO_{z/2}F_{4-z} (0<z<4), SrMgO_{z}/2F_{4-z} (0<z<4), Ba₁₋ₓSrₓMgO_{z}/2F_{4-z} (0<x<1, 0<z<4), BaZnO_{z/2}F_{4-z} (0<<<4), Ba_{1-y}(Mg₁₋ₓZnₓ)_{1+y}O_{z/2}F_{4-z} (0≤x≤1, −0.2≤y≤0.2, 0<z<4), or any combination thereof, but is not limited thereto.

A thickness of the inorganic intermediate layer 130 may be less than or equal to about 10 nm, and within the above range about 1 nm to about 10 nm, about 2 nm to about 10 nm, about 2 nm to about 8 nm, about 2 nm to about 6 nm, or about 2 nm to about 5 nm.

Since the exciton amplified in the organic intermediate layer 120 is transferred to the semiconductor substrate 110 through the inorganic intermediate layer 130, no separate electrode or circuit is required or needed or used to transfer charges from the organic intermediate layer 120 to the semiconductor substrate 110. Therefore, the process may be more easily simplified and the image sensor 100 may be miniaturized or improved/reduced in size.

Electrodes and circuits (not shown) may be additionally provided under the semiconductor substrate 110.

A focusing lens 140 may be formed on the color filter layer 70. The focusing lens 140 may control the direction of incident light and focus the light at one point. The focusing lens 140 may be, for example, cylindrical or hemispherical or parabolic in shape, but is not limited thereto.

As described above, the image sensor 100 includes an organic intermediate layer 120 including a singlet fission material and an inorganic intermediate layer 130 between the color filter layer 70 and the semiconductor substrate 110, and thereby amplified (e.g. approximately doubled) excitons may be generated by splitting from the singlet state (S1) excited by light absorption to the triplet state (T1) and these amplified excitons are transferred to the photodiodes 50a, 50b, and 50c within the semiconductor substrate 110 to effectively increase the efficiency of the image sensor. Therefore, the external quantum efficiency (EQE) of the image sensor 100 in at least one of the red wavelength spectrum, green wavelength spectrum, or blue wavelength spectrum transmitted through the first, second, or third color filters 70a, 70b, and 70c may be higher than the maximum external quantum efficiency of an inorganic photodiode (not including the organic intermediate layer 120) in the same wavelength spectrum.

For example, the maximum external quantum efficiency of the image sensor 100 may be about 10% or more greater than the maximum external quantum efficiency of the inorganic photodiode, within the above range, or about 15% or more, about 20% or more, or about 25% or more higher. For example, the maximum external quantum efficiency of the image sensor 100 may be about 80% to about 200%, about 85% to about 200%, about 90% to about 200%, about 95% to about 200%, about 100% to about 200%, about 80% to about 150%, about 85% to about 150%, about 90% to about 150%, about 95% to about 150%, about 100% to about 150%, about 80% to about 120%, about 85% to about 120%, about 90% to about 120%, about 95% to about 120%, or about 100% to about 120%.

For example, the maximum external quantum efficiency of the image sensor 100 in at least one of the red wavelength spectrum, the green wavelength spectrum, or the blue wavelength spectrum may exceed about 100%, and within the above range, about 100% to about 200%, about 100% to about 150% or about 100% to about 120%.

The image sensor 100 may be applied to or included in various electronic devices. Electronic devices may be applied to or included in, for example, one or more of cameras, mobile phones, video phones, smart phones, mobile phones, smart pads, smart watches, digital cameras, tablet PCs, laptop PCs, notebook computers, computer monitors, wearable computers, televisions, digital broadcasting terminals, e-books, personal digital assistants (PDAs), portable multimedia player (PMP), enterprise digital assistant (EDA), head mounted display (HMD), vehicle navigation, Internet of Things (IoT), Internet of all things (IoE), drones, door locks, safes, automatic teller machines (ATM), security devices, medical devices, or automotive electronic components, but are not limited thereto.

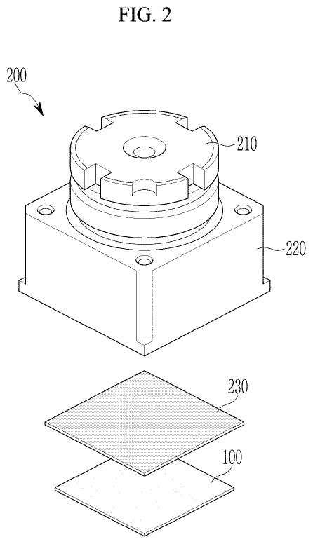

FIG. 2 is a schematic view illustrating an example of a camera, which is an example of an electronic device according to various example embodiments.

Referring to FIG. 2, the camera 200 includes a lens barrel 210, a housing 220, an optical filter 230, and an image sensor 100.

The lens barrel 210 includes at least one lens imaging a subject, and the lens may be disposed along an optical axis direction. Herein, the optical axis direction may be a vertical direction of the lens barrel 210. The lens barrel 210 is internally housed in the housing 220 and united with the housing 220. The lens barrel 210 may be moved in optical axis direction inside the housing 220 for autofocusing.

The housing 220 is intended to support and accommodate the lens barrel 210. The housing 220 may have an open shape in the direction of the optical axis or may be designed to be characteristically vertical using a prism or the like. Accordingly, light incident from one side of the housing 220 may reach the image sensor 100 through the lens barrel 210 and the optical filter 230.

The housing 220 may be equipped with an actuator (not illustrated) for moving the lens barrel 210 in the optical axis direction. The actuator may include a voice coil motor (VCM) including a magnet and a coil (not illustrated). However, various methods such as a mechanical driving system and/or a piezoelectric driving system using a piezoelectric device other than the actuator may alternatively or additionally be adopted.

The optical filter 230 may be configured to block light in a wavelength spectrum other than visible light and transmit light in the visible light wavelength spectrum. The optical filter 230 may include, for example, a near-infrared absorbing material capable of absorbing at least portion of the light in the wavelength spectrum of about 800 nm to about 3 μm. An average light transmittance (TVIS) for the visible light wavelength spectrum of the optical filter 230 may be greater than or equal to about 80%, and within the above range, greater than or equal to about 85%, greater than or equal to about 88%, greater than or equal to about 90%, greater than or equal to about 93%, greater than or equal to about 95%, greater than or equal to about 97%, or greater than or equal to about 99%. Herein, the visible light wavelength region may be a wavelength spectrum ranging from about 400 nm to about 750 nm, for example, from about 430 nm to about 565 nm.

The image sensor 100 is as described above and may generate an image signal by focusing light that has passed through the lens barrel 210 and the optical filter 230. The image sensor 100 may focus the image of the subject and store it as data, and the stored data may be displayed as an image through a display medium. The image sensor 100 may be mounted on a board (not shown) and may be electrically connected to the board. The substrate may be or include, for example, a printed circuit board (PCB) and/or be electrically connected to a printed circuit board, and the printed circuit may be or include, for example, a flexible printed circuit (FPCB).

Hereinafter, various embodiments are illustrated in more detail with reference to examples. However, these examples are examples, and the present scope is not limited thereto.

### Preparation of Organic Film

### Preparation Example 1

Compound A (a singlet fission material) is thermally vacuum-deposited respectively on a transparent quartz substrate and an Si wafer at 0.35 Å/min under vacuum of about 10-7 torr or less at 130° C. to form each 30 nm-thick organic film. Subsequently, the organic film is protected through glass encapsulation. Herein, the organic film formed on the transparent quartz substrate is for measuring an extinction coefficient and fission efficiency of the singlet fission material, and the organic film formed on the Si wafer is for measuring a HOMO energy level of the singlet fission material.

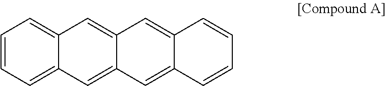 [SMILES: c1ccc2cc3cc4ccccc4cc3cc2c1]

### Preparation Example 2

An organic film is formed in the same manner as in Preparation Example 1 except that Compound B is used instead of Compound A (however, a deposition temperature of Compound B may be different from that of Compound A).

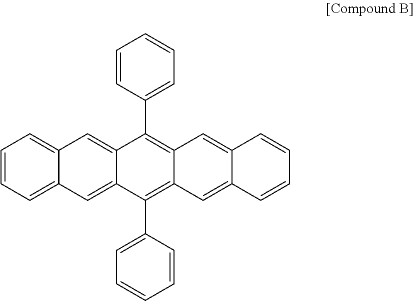 [SMILES: c1ccc(-c2c3cc4ccccc4cc3c(-c3ccccc3)c3cc4ccccc4cc23)cc1]

### Preparation Example 3

An organic film is formed in the same manner as in Preparation Example 1 except that Compound C is used instead of Compound A (a deposition temperature of Compound C may be different from that of Compound A).

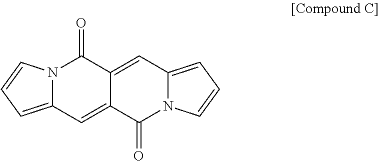 [SMILES: O=c1c2cc3cccn3c(=O)c2cc2cccn12]

### Preparation Example 4

An organic film is formed in the same manner as in Preparation Example 1 except that Compound D is used instead of Compound A (a deposition temperature of Compound D may be different from, e.g., greater than or less than, that of Compound A).

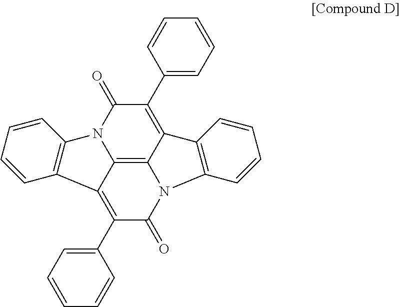 [SMILES: O=c1c(-c2ccccc2)c2c3ccccc3n3c(=O)c(-c4ccccc4)c4c5ccccc5n1c4c23]

### Preparation Example 5

An organic film is formed in the same manner as in Preparation Example 1 except that Compound E is used instead of Compound A (however, a deposition temperature of Compound E may be different from (e.g., greater than or less than) that of Compound A).

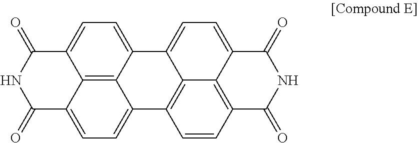 [SMILES: O=C1NC(=O)c2ccc3c4ccc5c6c(ccc(c7ccc1c2c73)c64)C(=O)NC5=O]

### Preparation Example 6

An organic film is formed in the same manner as in Preparation Example 1 except that Compound F is used instead of Compound A (however, a deposition temperature of Compound F may be different from e.g., greater than or less than, that of Compound A).

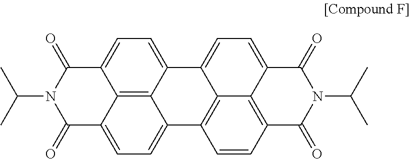 [SMILES: CC(C)N1C(=O)c2ccc3c4ccc5c6c(ccc(c7ccc(c2c37)C1=O)c64)C(=O)N(C(C)C)C5=O]

### Preparation Example 7

An organic film is formed in the same manner as in Preparation Example 1 except that Compound G is used instead of Compound A (however, a deposition temperature of Compound G may be different from e.g., greater than or less than, that of Compound A).

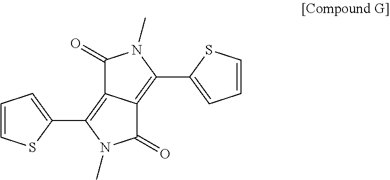 [SMILES: CN1C(=O)C2=C(c3cccs3)N(C)C(=O)C2=C1c1cccs1]

### Reference Preparation Example

An organic film is formed in the same manner as in Preparation Example 1 except that Compound H is used instead of Compound A (however, a deposition temperature of Compound H may be different from e.g., greater than or less than, that of Compound A).

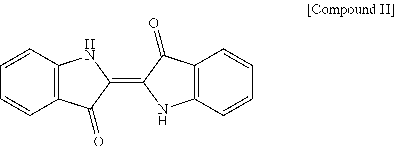 [SMILES: O=C1/C(=C2\Nc3ccccc3C2=O)Nc2ccccc21]

### Evaluation I

The organic films according to Preparation Examples and Reference Preparation Example are evaluated with respect to exciton energy E (S1) in a singlet state of Compounds A to H and exciton energy E(T1) in a triplet state thereof.

The exciton energy E(S1) and E(T1) in the singlet or triplet state is a DFT calculation value obtained by using DGDZVP basis sets under B3LYP functional conditions.

The results are shown in Table 1.

TABLE 1

| | | E | E |
|---|---|---|---|
| | | (S₁, eV) | (T₁, eV) |
| Preparation Example 1 | Compound A | 2.69 | 1.46 |
| Preparation Example 2 | Compound B | 2.07 | 0.85 |
| Preparation Example 3 | Compound C | 2.53 | 1.27 |
| Preparation Example 4 | Compound D | 2.50 | 1.38 |
| Preparation Example 5 | Compound E | 2.55 | 1.49 |
| Preparation Example 6 | Compound F | 2.53 | 1.48 |
| Preparation Example 7 | Compound G | 2.44 | 1.04 |
| Reference Preparation Example | Compound H | 2.34 | 1.04 |

### Evaluation II

The organic films according to Preparation Examples and Reference Preparation Example are evaluated with respect to an extinction coefficient, light transmittance, and singlet fission efficiency.

The extinction coefficient is obtained by measuring transmittance (T) and reflectance (R) within a region of 300 nm to 800 nm with Shimadzu UV-3600 Plus UV-Vis-NIR, a UV-Vis-NIR spectrometer and also, using Relation Formula 3 to calculate absorbance (A) at a maximum absorption wavelength (λmax) and then, dividing the absorbance (A) with a thickness of each organic film and Ln10.

$$A = 100 - T - R \qquad [ Relation Formula 3 ]$$

In Relation Formula 3, A is absorbance, T is transmittance, and R is reflectance.

The singlet fission efficiency is calculated from kmon and kfiss according to Relation Formula 2. Herein, kmon is a fluorescence decay rate of a singlet fission material in a solution state and specifically, evaluated as a reciprocal number of fluorescence decay time obtained from transient photoluminescence (Tr-PL, PicoQuant_FluoTime 300) in a diluted solution state of the singlet fission material. kfiss is a fission rate of the singlet fission material in a thin film and evaluated as a reciprocal of the fluorescence decay time in the thin film state obtained from the Tr-PL measurement.

The results are shown in Table 2.

TABLE 2

| | | Extinction | | 1/ | 1/ | |
|---|---|---|---|---|---|---|
| | | coefficient | T_{org} | kₘₒₙ | k_{fiss} | Φ_{fiss} |
| | | (@λₘₐₓ, cm⁻¹) | (%) | (ns) | (ns) | (%) |
| Preparation | Compound | 7.78 × 10⁴ | 48.6 | 3.8 | 0.151 | 96.2 |
| Example 1 | A | | | | | |
| Preparation | Compound | 2.7 × 10⁴ | 30.3 | 5.25 | 0.832 | 86.3 |
| Example 2 | B | | | | | |
| Preparation | Compound | 1.9 × 10⁴ | 22.5 | 5.27 | 1.30 | 74 |
| Example 3 | C | | | | | |
| Preparation | Compound | 3.70 × 10⁴ | 34.8 | 6.502 | 0.73 | 85 |
| Example 4 | D | | | | | |
| Preparation | Compound | 14.6 × 10⁴ | 67.38 | 2.804 | 0.072 | 97.5 |
| Example 5 | E | | | | | |
| Preparation | Compound | 8.46 × 10⁴ | 46.7 | 4.685 | 1.35 | 77.6 |
| Example 6 | F | | | | | |
| Preparation | Compound | 1.8 × 10⁴ | 22.7 | 5.70 | 2.63 | 68.4 |
| Example 7 | G | | | | | |
| Reference | Compound | 7.8 × 10⁴ | 30.1 | 0.2 | 0.206 | 49.2 |
| Preparation | H | | | | | |
| Example | | | | | | |

### Image Sensor

### Example 1

An image sensor in which the organic film according to Preparation Example 1 is laminated on an Si photodiode (Eg=1.1 eV) is set up.

### Example 2

An image sensor in which the organic film according to Preparation Example 2 instead of the organic film according to Preparation Example 1 is laminated is set up.

### Example 3

An image sensor in which the organic film according to Preparation Example 3 instead of the organic film according to Preparation Example 1 is laminated is set up.

### Example 4

An image sensor in which the organic film according to Preparation Example 4 instead of the organic film according to Preparation Example 1 is laminated is set up.

### Example 5

An image sensor in which the organic film according to Preparation Example 5 instead of the organic film according to Preparation Example 1 is laminated is set up.

### Example 6

An image sensor in which the organic film according to Preparation Example 6 instead of the organic film according to Preparation Example 1 is laminated is set up.

### Example 7

An image sensor in which the organic film according to Preparation Example 7 instead of the organic film according to Preparation Example 1 is laminated is set up.

### Reference Example 1

An image sensor is set up by using the Si photodiode alone but no organic film.

### Reference Example 2

An image sensor in which the organic film according to Reference Preparation Example instead of the organic film according to Preparation Example 1 is laminated is set up.

### Evaluation III

The image sensors of Examples and Reference Examples are evaluated with respect to external quantum efficiency (EQE).

The external quantum efficiency (EQE) is calculated according to Relation Formula 4 based on values listed in Table 2.

$${EQE}_{max} ( \% ) = {EQE}_{s i} \times {T}_{o r g} + 2 \times {Φ}_{f i s s} ( 1 - {T}_{o r g} ) \qquad [ Relation Formula 4 ]$$

In Relation Formula 4, EQEmax is an external quantum efficiency of the image sensor, EQEsi is an external quantum efficiency of the image sensor according to Reference Example 1 (calculated external quantum efficiency of silicon), Torg is a light transmittance of the organic film, and ϕfiss is a singlet fission efficiency of the singlet fission material of the organic film.

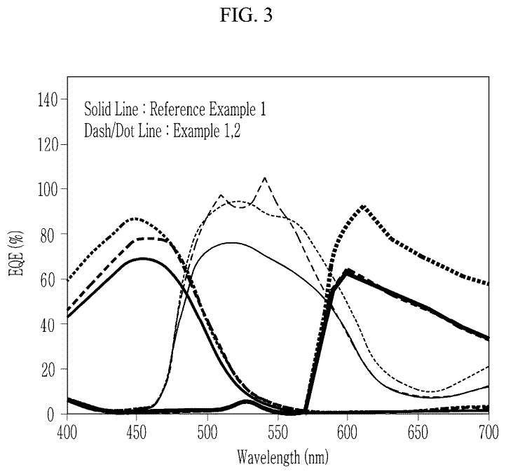

The results are shown in Table 3 and FIGS. 3 to 6.

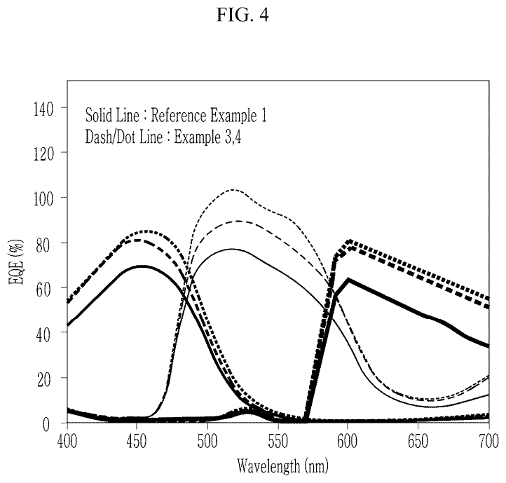

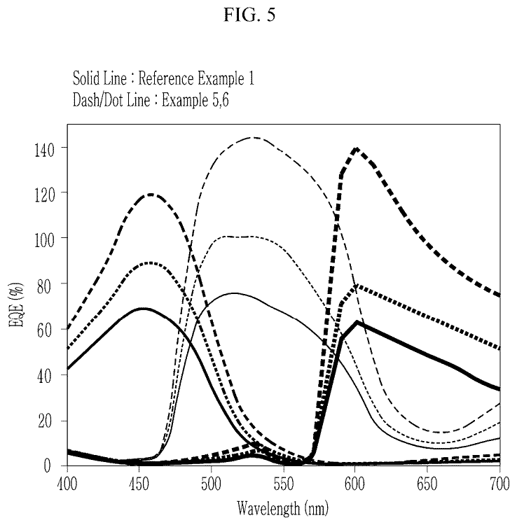

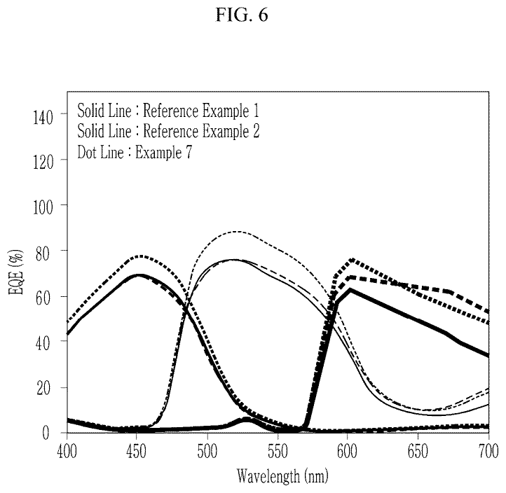

FIG. 3 is a graph showing the external quantum efficiency according to the wavelength of the image sensors according to Examples 1 and 2 and Reference Example 1, FIG. 4 is a graph showing the external quantum efficiency according to the wavelength of the image sensors according to Examples 3 and 4 and Reference Example 1, FIG. 5 is a graph showing the external quantum efficiency according to the wavelength of the image sensors according to Examples 5 and 6 and Reference Example 1, and FIG. 6 is a graph showing the external quantum efficiency according to the wavelength of the image sensors according to Example 7 and Reference Examples 1 and 2.

TABLE 3

| | EQE (%) |
|---|---|
| Example 1 | 106 |
| Example 2 | 94.8 |
| Example 3 | 88.5 |
| Example 4 | 101.9 |
| Example 5 | 144 |
| Example 6 | 101 |
| Example 7 | 87.9 |
| Reference Example 1 | 75.4 |
| Reference Example 2 | 75.2 |

Referring to Table 3 and FIGS. 3 to 6, the image sensors according to Examples, compared with the image sensors according to Reference Examples, exhibit improved external quantum efficiency for at least two or more spectra among red, green, and blue spectra and realize high external quantum efficiency of greater than about 85%, greater than about 90%, greater than about 95%, or greater than about 100%.

While this disclosure has been described in connection with what is presently considered to be various practical example embodiments, it is to be understood that the invention is not limited to the disclosed example embodiments. On the contrary, it is intended to cover various modifications and equivalent arrangements included within the spirit and scope of the appended claims. Furthermore, example embodiments are not necessarily mutually exclusive with one another. For example, some example embodiments may include one or more features described with reference to one or more figures, and may also include one or more other features described with reference to one or more other figures.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Moreover, when the words “generally” and “substantially” are used in connection with material composition, it is intended that exactitude of the material is not required but that latitude for the material is within the scope of the disclosure.

Further, regardless of whether numerical values or shapes are modified as “about” or “substantially,” it will be understood that these values and shapes should be construed as including a manufacturing or operational tolerance (e.g., ±10%) around the stated numerical values or shapes. Thus, while the term “same,” “identical,” or “equal” is used in description of example embodiments, it should be understood that some imprecisions may exist. Thus, when one element or one numerical value is referred to as being the same as another element or equal to another numerical value, it should be understood that an element or a numerical value is the same as another element or another numerical value within a desired manufacturing or operational tolerance range (e.g., ±10%).

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

What is claimed is:

1. An image sensor comprising:
a semiconductor substrate comprising a plurality of photodiodes;
a color filter layer on the semiconductor substrate, the color filter layer comprising a plurality of color filters arranged along an in-plane direction of the semiconductor substrate; and
an organic intermediate layer between the semiconductor substrate and the color filter layer, the organic intermediate layer comprising a singlet fission material,
wherein an extinction coefficient of the organic intermediate layer at a maximum absorption wavelength is greater than or equal to 1×10⁴ cm⁻¹, and
a singlet fission efficiency of the organic intermediate layer is greater than 50%.

2. The image sensor of claim 1, wherein the singlet fission material is an organic material that has an energy level according to Relation Formula 1:
$$E ( {S}_{1} ) + 0.5 eV \geq 2 \times E ( {T}_{1} ) \qquad [ Relation Formula 1 ]$$
wherein, in Relation Formula 1,
E(S₁) corresponds to an excitation energy in a lowest singlet excited state of the singlet fission material,
E(T₁) corresponds to an excitation energy in a lowest triplet excited state of the singlet fission material, and
E(S₁) and E(T₁) are density functional theory (DFT) calculation values.

3. The image sensor of claim 1, wherein an extinction coefficient of the organic intermediate layer at a maximum absorption wavelength is between 1.5×10⁴ cm⁻¹ to 1.0×10⁶ cm⁻¹.

4. The image sensor of claim 1, wherein a singlet fission efficiency of the organic intermediate layer is between 65% to 100%.

5. The image sensor of claim 1, wherein
the photodiode comprises an inorganic semiconductor, and
an excitation energy in a triplet state of the singlet fission material is greater than or equal to an energy bandgap of the inorganic semiconductor of the photodiode.

6. The image sensor of claim 1, wherein the organic intermediate layer further comprises a phosphorescent dopant.

7. The image sensor of claim 6, wherein
the photodiode comprises an inorganic semiconductor, and
an energy bandgap of the phosphorescent dopant is greater than or equal to an energy bandgap of the inorganic semiconductor of the photodiode.

8. The image sensor of claim 1, wherein the maximum absorption wavelength of the singlet fission material is within 380 nm to 700 nm.

9. The image sensor of claim 1, wherein the singlet fission material is configured to absorb light in at least two wavelength spectra from among a red wavelength spectrum, a green wavelength spectrum, or a blue wavelength spectrum.

10. The image sensor of claim 1, further comprising:
an inorganic intermediate layer between the semiconductor substrate and the organic intermediate layer.

11. The image sensor of claim 10, wherein the inorganic intermediate layer comprises at least one of an oxide, nitride, oxynitride, fluoride or oxyfluoride comprising a metal or a semi-metal.

12. The image sensor of claim 10, wherein a thickness of the inorganic intermediate layer is 1 nm to 10 nm.

13. The image sensor of claim 1, wherein the image sensor exhibits an external quantum efficiency of greater than about 100%.

14. An image sensor configured to obtain an image by combining image signals obtained by photoelectrically converting light in a red wavelength spectrum, a green wavelength spectrum, and a blue wavelength spectrum, the image sensor comprising
a color filter layer comprising a first color filter configured to selectively transmit light included in a red wavelength spectrum, a second color filter configured to selectively transmit light included in a green wavelength spectrum, and a third color filter configured to selectively transmit light included in a blue wavelength spectrum,
an organic intermediate layer comprising an organic singlet fission material configured to absorb light transmitted through the color filter layer, to convert the absorbed light into photoelectricity and satisfying an energy level of Relation Formula 1,
an inorganic photodiode on the organic intermediate layer, and
an inorganic intermediate layer between the organic intermediate layer and the inorganic photodiode, the inorganic intermediate layer comprising at least one of an oxide, nitride, oxynitride, fluoride or oxyfluoride comprising a metal or a semi-metal, or any combination thereof, wherein
a maximum external quantum efficiency of the image sensor in at least one of a red wavelength spectrum, a green wavelength spectrum, and a blue wavelength spectrum is greater than a maximum external quantum efficiency of the inorganic photodiode in the same wavelength spectrum, and Reaction Formula 1 is given as
$$E ( {S}_{1} ) + 0.5 eV \geq 2 \times E ( {T}_{1} ) \qquad [ Relation Formula 1 ]$$
wherein, in Relation Formula 1,
E(S₁) corresponds to an excitation energy in a lowest singlet excited state of the singlet fission material,
E(T₁) corresponds to an excitation energy in a lowest triplet excited state of the singlet fission material, and
E(S₁) and E(T₁) are density functional theory (DFT) calculation values.

15. The image sensor of claim 14, wherein an external quantum efficiency of the image sensor in at least one of the red wavelength spectrum, the green wavelength spectrum, or the blue wavelength spectrum is greater than 100%.

16. The image sensor of claim 14, wherein
an extinction coefficient of the organic intermediate layer at a maximum absorption wavelength is greater than or equal to 1×10⁴ cm⁻¹, and
a singlet fission efficiency of the organic intermediate layer is greater than 50%.

17. The image sensor of claim 16, wherein
an extinction coefficient of the organic intermediate layer at a maximum absorption wavelength is greater than or equal to 1.5×10⁴ cm⁻¹ to 1.0×10⁶ cm⁻¹, and
a singlet fission efficiency of the organic intermediate layer is 65% to 100%.

18. The image sensor of claim 14, wherein the organic material is configured to absorb light in at least two of the red wavelength spectrum, the green wavelength spectrum or the blue wavelength spectrum.

19. The image sensor of claim 14, wherein
the organic intermediate layer further comprises a phosphorescent dopant, and
an energy bandgap of the phosphorescent dopant is greater than or equal to that of the inorganic photodiode,

20. An electronic device comprising the image sensor of claim 1.
